(19) United States
(12) Patent Application Publication
(10) Pub. No.: US 2022/0090294 A1
(43) Pub. Date: Mar. 24, 2022

(54) METHOD FOR GROWING A SEMI-POLAR GALLIUM NITRIDE EPITAXIAL LAYER USING ALUMINUM NITRIDE / GALLIUM NITRIDE SUPERLATTICES

(71) Applicant: COLLABORATIVE RESEARCH IN ENGINEERING, SCIENCE AND TECHNOLOGY CENTER, Bayan Lepas (MY)

(72) Inventors: Ahmad Shuhaimi BIN ABU BAKAR, Kuala Lumpur (MY); Omar Ayad Fadhil AL- ZUHAIRI, Kuala Lumpur (MY); Abdullah Haaziq AHMAD MAKINUDIN, Kuala Lumpur (MY); Mohd Adreen Shah BIN AZMAN SHAH, Kuala Lumpur (MY); Anas BIN KAMARUNDZAMAN, Kuala Lumpur (MY)

(21) Appl. No.: 17/422,197

(22) PCT Filed: Jan. 17, 2019
(86) PCT No.: PCT/MY2019/000004

§ 371 Date: Jul. 11, 2021

(51) Int. Cl. C30B 25/18; C30B 29/40; C30B 29/68

(52) U.S. Cl. CPC C30B 25/186; C30B 29/403; H01L 33/007; C30B 29/68; C30B 29/406

(57) ABSTRACT

A method for growing a semi-polar gallium nitride epitaxial layer by inserting aluminum nitride and gallium nitride multi-layers includes the steps of cleaning m-sapphire substrates and activating the m-sapphire substrates by utilizing a combination of precursors and carrier gas. The method of growing a layer of semi-polar gallium nitride epitaxial layer on m-sapphire substrates further includes nitridating for initiating growth sequence and depositing a nucleation layer. The film stack of aluminum nitride and gallium nitride multi-layers is grown to initiate growth of a super lattice layer on m-plane sapphire substrates. Subsequently, a layer of the undoped gallium nitride is deposited on the m-plane sapphire substrate.

### CROSS-REFERENCE TO RELATED APPLICATIONS

See Application Data Sheet.

### STATEMENT REGARDING FEDERALLY SPONSORED RESEARCH OR DEVELOPMENT

Not applicable.

### THE NAMES OF PARTIES TO A JOINT RESEARCH AGREEMENT

Not applicable.

### INCORPORATION-BY-REFERENCE OF MATERIAL SUBMITTED ON A COMPACT DISC OR AS A TEXT FILE VIA THE OFFICE ELECTRONIC FILING SYSTEM (EFS-WEB)

Not applicable.

### STATEMENT REGARDING PRIOR DISCLOSURES BY THE INVENTOR OR A JOINT INVENTOR

Not applicable.

### BACKGROUND OF THE INVENTION

### 1. Field of the Invention

Embodiments of the present invention relate to a method for growing a semi-polar gallium nitride epitaxial layer on m-plane crystal sapphire, in particular relates a Metal-Organic Chemical Vapour Deposition (MOCVD) method to improve surface morphology and crystal quality.

### 2. Description of Related Art Including Information Disclosed Under 37 CFR 1.97 and 37 CFR 1.98

With the advent in semiconductor technology, gallium nitride (GaN) and its related compounds are leading components for fabrication of advanced visible and ultraviolet high-power and high-performance optoelectronic devices and electronic devices. Particularly, these devices are typically grown epitaxially by various growth techniques including molecular beam epitaxy (MBE), metalorganic chemical vapor deposition (MOCVD), or hydride vapor phase epitaxy (HVPE).

Conventionally, the gallium nitride semiconductor materials and devices have been developed through crystal growth in c-plane direction. Due to lack of mirror-like and two-fold symmetry of the hexagonal crystal structure, spontaneous polarization occurs on the c-plane. Additionally, strain in lattice mismatched hetero-epitaxially grown device layers result in piezoelectric polarization, Particularly, the piezoelectric polarization results in large built-in electric fields, hampering the performance of nitride-based devices. Moreover, the built-in polarization fields in optical devices also causes charge separation within quantum wells. Due to charge separation the recombination efficiency of electron-hole pairs decreases the emission wavelengths. Thus, selection of substrate is very critical for achieving the desired gallium nitride growth orientation.

Non-polar gallium nitride is gaining attention due to position of its crystal structure allowing high internal quantum efficiency without facing the quantum-confined Stark effect (QCSE). Additionally, the arrowhead-like features prevailing on the surface of the semi-polar gallium nitride are grown on m-plane sapphire substrates due to the lattice mismatch. Recently, more attention is given to the development of nitride epitaxial layers and heterostructures with non-polar and semi-polar crystal orientations.

Particularly, the gallium nitride-based quantum structures are grown along non-polar directions to be free of the aforementioned polarization effects. Moreover, to improve the surface morphology and crystal activity many different approaches have been employed. One of the approaches involves the heteroepitaxial growth of non-polar gallium nitride on non-native non-gallium nitride or other nitride substrates.

There have been developments in the field of growing gallium nitride. U.S. Pat. No. 7,338,828B2 published on Apr. 3, 2008 focuses on a method of growing planar non-polar m-plane gallium nitride on m-plane silicon carbide (m-SiC) substrate via metalorganic chemical vapor deposition (MOCVD). However, due to the lattice mismatch generated between the m-plane and the epitaxial layers gallium nitride has poor surface morphology with undulated surface striations, arrowhead -like and faceted pits.

The U.S. Pat. No. 7,220,324B2 published on 22 May 2007 discloses a method focusing on growing planar semi-polar gallium nitride via HVPE method to improve indium incorporation and achieved semi-polar epitaxial layers. However, the growth Is in a direction parallel to the substrate surface.

The above-mentioned methods have been reported to improve crystal quality but suffer from limitations such as basal stacking faults, associated partial dislocation (PDs) and perfect dislocation. The most common technique to improve the crystal quality of semi-polar epitaxial layer is the epitaxial lateral overgrowth (ELOG). However, epitaxial lateral overgrowth (ELOG) requires additional steps and re-growth in ex-situ environment.

Thus, there is a need to develop a method for growing gallium nitride in order to overcome the gap of the existing technology. The present technique helps in addressing the existing problems by focusing on growing semi-polar gallium nitride on m-plane (10-10) sapphire substrate by inserting aluminum nitride and gallium nitride multi-layers. Additionally, the method improves the crystal quality and surface morphology without any foreign materials interrupting the growth and substrate patterning.

### BRIEF SUMMARY OF THE INVENTION

The embodiment of present invention relates to a method for growing a semi-polar gallium nitride epitaxial layer. Particularly, the method includes the steps of cleaning one or more m-sapphire substrates to remove contamination from the m-sapphire substrates and activating the m-sapphire substrates. Moreover, the m-sapphire substrates are activated by utilizing a combination of one or more of precursors and a carrier gas. Furthermore, one or more precursors are selected from trimethyl-gallium (TMGa), trimethyl-aluminium (TMAI) and ammonia (NH3), Additionally, the hydrogen gas is utilized as the carrier gas for activation of the sapphire substrates. Subsequently, the hydrogen gas cleans the m-sapphire substrates at a relatively high temperature of about 1125° C. to remove contamination.

One embodiment of present invention relates to the steps of nitridation while growing semi-polar gallium nitride epitaxial layer on the m-sapphire substrates. Particularly, nitridation initiates the growth sequence. Moreover, the nitridation is carried out at a temperature of about 1050° C. for about 30 minutes. Furthermore, the nitridation is performed on a portion of one or more of m-sapphire substrates having a plane orientation of m-plane [10-10]. Subsequently, the semi-polar gallium nitride epitaxial layer has plane orientation of [11-22].

Another embodiment of present Invention relates to deposition of nucleation layer. Particularly, the nucleation layer is deposited on the m-sapphire substrates. Moreover, the deposition of nucleation layer reduces the interfacial stresses between the epitaxial layer and the m-sapphire substrate, Furthermore, the nucleation layer deposited on m-sapphire substrates is an aluminum nitride nucleation layer. Subsequently, the nucleation layer has a thickness of about 60 nanometers (nm) to about 100 nanometers (nm).

Yet another embodiment of present invention relates to the film stack of aluminum nitride and gallium nitride multi-layers. Particularly, the film stack initiates the growth of semi-polar gallium nitride on a super lattice layer at a temperature of about 1050° C. Moreover, the superlattice layer is grown on the m-plane sapphire substrate. Furthermore, gallium nitride is grown on the superlattice layer at a temperature of about 1050° C. on a two-dimensional plane. Subsequently, the film stack is formed from about 60 pairs of aluminum nitride and gallium nitride multi-layers. Henceforth, the film stack has a thickness in ratio of about 5 nanometers (nm) of aluminum nitride to about 10-20 nanometers (nm) of gallium nitride. Additionally, a layer of undoped gallium nitride is also deposited on the m-plane sapphire substrate. The layer of undoped gallium nitride has a thickness of about 4.5 mm.

Yet another embodiment of present invention relates to defects propagating from the interface of gallium nitride and m-sapphire substrates. Particularly, defects along semi polar [11-22] gallium nitride. Moreover, the defects also were blocked by the interface of aluminum nitride and gallium nitride due to lattice constants difference.

Particularly, the semi-polar gallium nitride epitaxial layer improves one or more parameters by inserting one or more aluminum nitride and gallium nitride multi-layers. Moreover, the multi layers are inserted between the nucleation layer and the undoped gallium nitride layer. Furthermore, one or more parameters are selected from surface morphology parameter and a crystal quality parameter. Subsequently, the method performs the insertion of aluminum nitride and gallium nitride multi-layers through metal organic chemical vapor deposition (MOCVD). Moreover, metal organic chemical vapor deposition (MOCVD) is a horizontal system.

In one embodiment of present invention the metal organic chemical vapor deposition (MOCVD) is Taiyo Nippon Sanso SR2000 series horizontal metal organic chemical vapor deposition (MOCVD). In use, the present invention does not limit to the specific model of MOCVD as disclosed above. However, any MOCVD system with similar or equivalently upscaled gas flow is able to replicate the growth.

### BRIEF DESCRIPTION OF THE SEVERAL VIEWS OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention that may admit to other equally effective embodiments.

FIG. 1 is a flowchart illustrating a method of growing a semi-polar gallium nitride epitaxial layer in accordance with one or more embodiments of the present invention.

FIG. 2A is a pictorial cross-sectional view of FESEM image illustrating semi-polar epitaxial layer grown on m-plane sapphire having aluminum nitride and gallium nitride multi-layers in accordance with one or more embodiments of the present invention.

FIG. 2B is a schematic diagram illustrating a plurality of semi-polar epitaxial layers grown on m-plane sapphires in accordance with one or more embodiments of the present invention.

FIG. 2C is a pictorial snapshot illustrating a high magnifying image of the 60 pairs of semi-polar aluminum nitride and gallium nitride multi-layers at a scale of 100 nm in accordance with one embodiment of the present invention.

FIG. 2D is a pictorial snapshot illustrating high magnification of the 60 pairs of semi-polar aluminum nitride and gallium nitride multi-layers at a scale of 50 nm in accordance with another embodiment of the present invention.

FIG. 3 is a pictorial snapshot depicting surface morphology for 60 pairs of AlN/GaN superlattices utilizing FESEM, in accordance with yet another embodiment of the present invention.

FIG. 4 is a pictorial snapshot depicting surface morphology for 60 pairs of AlN/GaN superlattices using AFM, in accordance with one embodiment of the present invention.

FIG. 5A is a graphical snapshot depicting XRC FWHM values as a function of azimuthal angle (F) for 60 pairs of AlN/GaN superlattices, in accordance with one or more embodiments of the present invention.

FIG. 5B is a graphical snapshot depicting XRC FWHM values along different angle values as a function of AlN/GaN pairs, in accordance with one or more embodiments of the present invention.

FIG. 6 is a pictorial snapshot illustrating the structure of gallium nitride with the insertion of aluminum nitride and gallium nitride multi-layers, in accordance with one or more embodiments of the present invention.

While the present method for growing a semi-polar gallium nitride epitaxial layer have been described herein by way of example for several embodiments and illustrative drawings, those skilled in the art will recognize that the present growing method is not limited to embodiments or drawings described. It should be understood that the drawings and detailed description thereto are not intended to limit embodiments to the particular form disclosed. Rather, the intention is to cover all modifications, equivalents and alternatives falling within the spirit and scope of the invention as defined by the appended claims.

Any headings used herein are for organizational purposes only and are not meant to limit the scope of the description or the claims. As used herein, the word “can” and “may” is used in a permissive sense (i.e., meaning having the potential to), rather than the mandatory sense (i.e., meaning must). Similarly, the words “include”, “including”, and “includes” mean including, but not limited to.

### DETAILED DESCRIPTION OF THE INVENTION

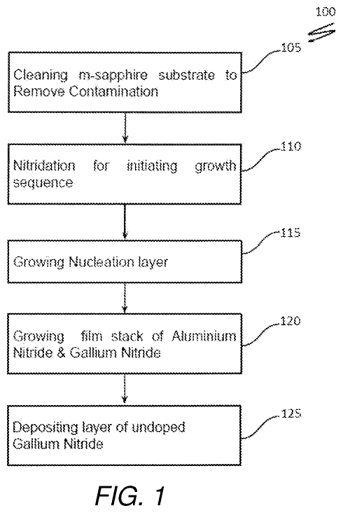

Various embodiments of the present invention relate to a method for growing a semi-polar gallium nitride epitaxial layer. Moreover, the principles of the present invention and their advantages are best understood by referring to FIG. 1 to FIG. 6. In the following detailed description of illustrative or exemplary embodiments of the disclosure, specific embodiments in which the disclosure may be practiced are described in sufficient detail to enable those skilled in the art to practice the disclosed embodiments. For example, specific details such as specific method steps, structures, elements, and connections are presented herein. However, it is to be understood that the specific details presented need not be utilized to practice the embodiments of the present disclosure. The following detailed description is, therefore, not to be taken in a limiting sense, and the scope of the present disclosure is defined by the appended claims and equivalents thereof.

References within the specification to “one embodiment,” “an embodiment” “embodiments,” or “one or more embodiments” are intended to indicate that a particular feature, structure, or characteristic described in connection with the embodiment is included in at least one embodiment of the present disclosure. The appearance of such phrases in various places within the specification are not necessarily all referring to the same embodiment, nor are separate or alterative embodiments mutually exclusive of other embodiments. Further, various features are described which may be exhibited by some embodiments and not by others. Similarly, various requirements are described which may be requirements for some embodiments, but not other embodiments.

FIG. 1 is a flowchart illustrating a method of growing the semi-polar gallium nitride epitaxial layer in accordance with one or more embodiments of the present invention. The method 100 of growing a semi-polar gallium nitride epitaxial layer starts at step 105 and proceeds to step 110. At step 105, one or more m-sapphire substrates are cleaned to remove contamination from the m-sapphire substrates. Particularly, the contamination is removed from the m-sapphire substrates by the hydrogen gas maintained at a relatively high temperature of about 1125° C. The step 105 of method 100 proceeds to step 110.

At step 110, nitridation is performed on the m-sapphire substrates.

Particularly, nitridation initiates growth sequences by diffusing one or more layers of nitrogen on the m-sapphire substrates. Moreover, the nitridation is carried out at a temperature of about 1050° C. for about 30 minutes.

Furthermore, the nitridation is performed on a portion of one or more of m-sapphire substrates having a plane orientation of m-plane [10-10].

The step 110 of method 100 proceeds to step 115. At step 115, nucleation layer is deposited on one or more m-sapphire substrates. Particularly, the deposition reduces the interfacial stresses between the epitaxial layers and m-sapphire substrate. Moreover, the nucleation layer deposited on the m-sapphire substrates is an aluminum nitride nucleation layer. Furthermore, the nucleation layer has a thickness of about 80 nanometers (nm) to about 100 nanometers (nm).

The step 115 of method 100 proceeds to step 120. At step 120, film stack of aluminum nitride and gallium nitride multi-layers are grown on the m-sapphire substrates. Particularly, the film stack is grown to initiate the growth of semi-polar gallium nitride on the super lattice layer. The film stack is grown at a temperature of about 1050° C. on the m-plane sapphire substrates. Moreover, the gallium nitride is grown on the super lattice layer at a temperature of about 1050° C. on a two-dimensional plane. The step 120 of method 100 proceeds to step 125. At step 125, a layer of undoped gallium nitride is deposited on one or more m-plane sapphire substrates. Particularly, the deposited layer of undoped gallium nitride has a thickness of about 4.5 mm.

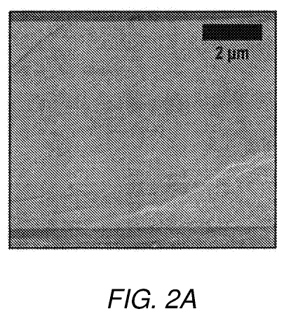

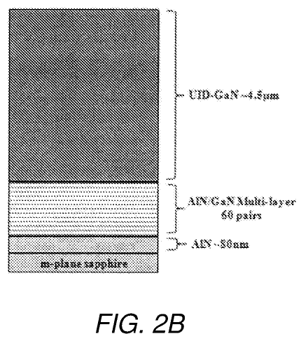

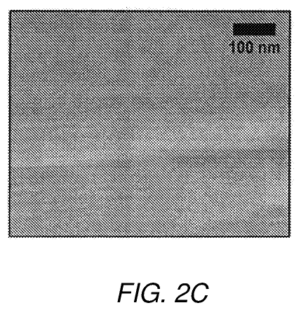

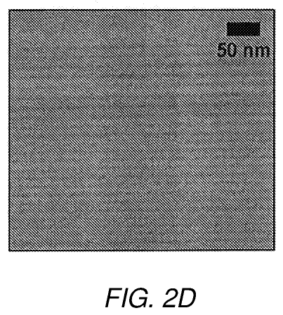

FIG. 2A is a pictorial cross-sectional view of FESEM image illustrating semi-polar [11-22] epitaxial layers grown on m-plane sapphire having aluminum nitride and gallium nitride multi-layers in accordance with one or more embodiments of the present invention, and FIG. 2B is a schematic diagram illustrating a plurality of semi-polar epitaxial layers grown on m-plane sapphire in accordance with one or more embodiments of the present invention. In accordance with FIG. 2A and FIG. 2B, the grown gallium nitride demonstrates a lateral two-dimensional (2D) growth. Particularly, the cross sectional FESEM Image in FIG. 2A illustrates an abrupt interface of aluminum nitride and gallium nitride multi-layers. Moreover, the film stack is formed from maximum of 60 pairs of aluminum nitride and gallium nitride multilayers. Furthermore, the film stack has a thickness in ratio of about 5 nanometers (nm) of aluminum nitride to about 10-20 nanometers (nm) of gallium nitride.

FIG. 2C is a pictorial snapshot illustrating a high magnifying image of the 60 pairs of semi-polar [11-22] aluminum nitride and gallium nitride multi-layers at a scale of 100 nm in accordance with one embodiment of the present invention and FIG. 2D is a pictorial snapshot illustrating high magnification of the 60 pairs of semi-polar [11-22] aluminum nitride and gallium nitride multi-layers at a scale of 50 nm in accordance with another embodiment of the present invention. Particularly, defects propagate from an interface of the gallium nitride and m-sapphire substrates. Moreover, the defect is along semipolar [11-22] gallium nitride. Furthermore, the propagation of defects is blocked at annihilating the interface of aluminum nitride and gallium nitride due to lattice constants difference.

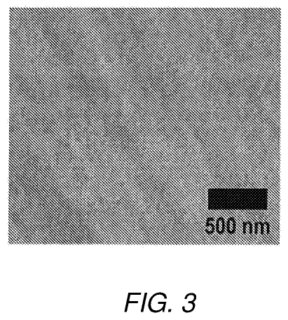

FIG. 3 is a pictorial snapshot depicting surface morphology for 60 pairs of AlN/GaN superlattices utilizing FESEM, in accordance with yet another embodiment of the present invention. Particularly, the semi-polar gallium nitride epitaxial layer improves one or more parameters by inserting one or more aluminum nitride layers and gallium nitride multi-layers. Moreover, the multi layers are inserted between the nucleation layer and the undoped gallium nitride layer. Furthermore, one or more parameters are selected from the surface morphology parameter and the crystal quality parameter. Subsequently, the parameters are selected for one or more semi-polar gallium nitride epitaxial layers.

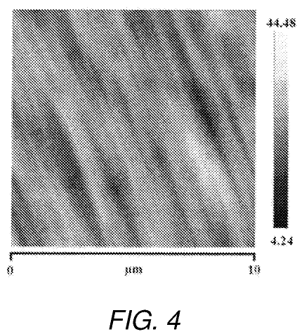

FIG. 4 is a pictorial snapshot depicting surface morphology for 60 pairs of AlN/GaN superlattices using AFM, In accordance with one embodiment of the present invention. Particularly, the grown gallium nitride is in range of 60 pairs of aluminium nitride and gallium nitride.

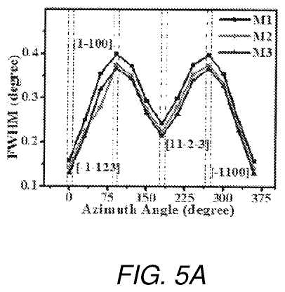

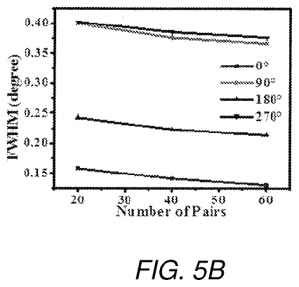

FIG. 5A is a graphical snapshot depicting XRC FWHM values as a function of azimuthal angle (F) for 60 pairs of AlN/GaN superlattices, in accordance with one or more embodiments of the present invention. Particularly, XRC full width half maximum (FWHM) values are along (11-22) w-scan. Moreover, the XRC full width half maximum (FWHM) value is a function of azimuthal angle [f]. Subsequently, the full width half maximum (FWHM) reduces with increasing number of the multi-layers. Henceforth, the number of multi-layers increase to about 60 pairs of aluminum nitride and gallium nitride.

FIG. 5B is a graphical snapshot depicting XRC FWHM values along different angle values as a function of aluminum nitride and gallium nitride pairs (AlN/GaN pairs), in accordance with one or more embodiments of the present invention. The different angle values are selected from 0°, 90°, 180° and 270° as a function of AlN/GaN pairs. Particularly, full width half maximum (FWHM) values are along [−1-123] plane and [1-100] plane. Moreover, full width half maximum (FWHM) is a function of aluminum nitride and gallium nitride pairs. Furthermore, the full width half maximum (FWHM) reduces with increasing number of the multi-layers. Henceforth, the multilayers increase to about 60 pairs of aluminum nitride and gallium nitride.

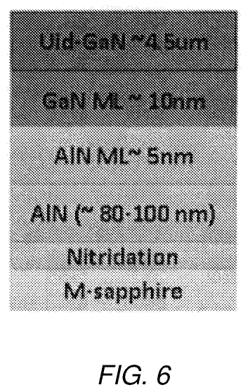

FIG. 6 is a pictorial snapshot illustrating the structure of gallium nitride with the insertion of aluminum nitride and gallium nitride multi-layers, in accordance with one or more embodiments of the present invention. Particularly, the semi-polar [11-22] gallium nitride epitaxial layer is grown by inserting aluminum nitride and gallium nitride multi-layers. In accordance with one embodiment of the present invention, multiple samples are grown on two-inch m-plane [10-10] sapphire substrates using a horizontal MOCVD system.

Prior to growing of epitaxial layer on two-inch sapphire substrate, the m-plane [1-102] sapphire substrate is cleaned. Moreover, the cleaning is performed in a hydrogen environment optimized to a temperature of about 1125° C. in order to remove the contamination. Furthermore, trimethyl-gallium (TMGa), trimethyl-aluminum (TMAI) and ammonia (NH₃) are used as precursors for gallium, aluminum and nitrogen respectively along with hydrogen gas as carrier gas for activating the m-sapphire substrates.

Particularly, the nitridation treatment is carried out on m-plane [10-10] sapphire substrates. Moreover, aluminum nitride nucleation layer is deposited onto the sapphire substrates. Furthermore, the aluminum nitride nucleation layer has a thickness of about 80 nm -100 nm. Subsequently, the aluminum nitride nucleation layer reduces the interfacial stresses between epitaxial layers and the sapphire substrates. The aluminum nitride and gallium nitride multi-layers are grown at a high temperature of about 1050° C. Furthermore, 4.5 mm thick layer of undoped gallium nitride is deposited on the aluminum nitride and gallium nitride multi-layers.

The present instant invention has an advantage of promoting a strain that tends to interact and annihilate the defects and dislocations generated from different lattice mismatch between the epitaxial layers and the foreign substrates. Accordingly, crystal quality of gallium nitride is enhanced. Moreover, the reduced defect and dislocation densities improve the surface morphology and crystal quality of gallium nitride. Due to the abovementioned advantages, the present invention provides improved surface morphology and crystal quality. Therefore, the present invention enhances the efficiency of produced Light Emitting Diodes (LEDs).

1. A method for growing a semi-polar gallium nitride epitaxial layer, the method comprising the steps of:
cleaning a plurality of m-sapphire substrates to remove contamination from said plurality of m-sapphire substrates;
growing a layer of a semi-polar gallium nitride epitaxial layer on said plurality of m-sapphire substrates being comprised of: nitridating for initiating growth sequence by diffusing at least one layer of ammonia (NH₃) gas into at least one m-sapphire substrate;
depositing a nucleation layer on said at least one m-sapphire substrate to reduce an interfacial stress between said epitaxial layer and said at least one m-sapphire substrate;
growing a film stack of an aluminum nitride and a gallium nitride to initiate growth of said semi-polar gallium nitride multi-layer; and
depositing a layer of an undoped gallium nitride on said at least one m-plane sapphire substrate,
wherein said semi-polar gallium nitride epitaxial layer is grown by inserting a plurality of aluminum nitride and gallium nitride multi-layers for improving at least one parameter.

2. The method as claimed in claim 1, wherein said insertion of said plurality of aluminum nitride and gallium nitride multi-layers are disposed between said nucleation layer and said undoped gallium nitride layer.

3. The method as claimed in claim 1, wherein said nitridation step is carried out at a temperature of about 1050° C. for about 30 minutes configured to initiate growth sequence.

4. The method as claimed in claim 1, wherein said film stack is grown at a temperature of about 1050° C.

5. The method as claimed in claim 1, wherein said gallium nitride is grown on said super lattice layer at a temperature of about 1050° C.

6. The method as claimed in claim 1, wherein said layer of undoped gallium nitride is having a thickness of about 4.5 mm.

7. The method as claimed in claim 1, wherein said nucleation layer has a thickness of about 80 nm to about 100 nm.

8. The method as claimed in claim 4, wherein said film stack is formed from said plurality of aluminum nitride and gallium nitride layers having minimum 20 pairs and maximum of 60 pairs of said aluminum nitride and said gallium nitride.

9. The method as claimed in claim 8, wherein said film stack is having a thickness in a ratio of about 5 nm of aluminum nitride to about 10-20 nm of gallium nitride.

10. The method as claimed in claim 1, wherein said nucleation layer deposited is comprised of an aluminum nitride nucleation layer.

11. The method as claimed in claim 1, wherein said carrier gas is comprised of a hydrogen gas, and wherein said hydrogen gas cleans said m-sapphire substrate at a relatively high temperature of about 1125° C. to remove contamination.

12. The method as claimed in claim 1, wherein said plurality of precursors is comprised of one of a group consisting of trimethyl-gallium (TMGa), trimethyl-aluminium (TMAI) and ammonia (NH₃).

13. The method as claimed in claim 2, wherein said method performs said insertion of said aluminum nitride and gallium nitride multi-layers is through metal-organic chemical vapour deposition (MOCVD) and wherein said metal-organic chemical vapour deposition (MOCVD) is a horizontal reactor.

14. The method as claimed in claim 13, wherein said metal-chemical vapour deposition (MOCVD) is a Taiyo Nippon Sanso SR2000 series horizontal metal-organic chemical vapour deposition (MOCVD) system.

15. The method as claimed in claim 1, wherein the step of nitridating is performed on a portion of said plurality of m-sapphire substrates having a plane orientation of m-plane [10-10] and said semi-polar gallium nitride epitaxial layer is having plane orientation of [11-22].

16. The method as claimed in claim 1, wherein the basal stacking faults propagates from an interface of said gallium nitride and said plurality of m-sapphire substrates propagates along on-axis semipolar [11-22] gallium nitride.

17. The method as claimed in claim 16, wherein propagation of said basal stacking faults are blocked at the interface of said aluminum nitride and said gallium nitride due to lattice constant difference.

18. The method as claimed in claim 1, wherein said semi polar gallium nitride layer grows on a two-dimensional plane.

19. The method as claimed in claim 1, wherein said at least one parameter is selected from a group consisting of: a surface morphology parameter and a crystal quality parameter.
